(19) United States
(12) Patent Application Publication
(10) Pub. No.: US 2015/0084508 A1
(43) Pub. Date: Mar. 26, 2015

(54) STRUCTURAL BODY AND ELECTRODE STRUCTURE

(71) Applicant: NGK INSULATORS, LTD., Nagoya-City (JP)

(72) Inventors: Yoshimasa KONDO, Nagoya-city (JP); Kunihiko YOSHIOKA, Nagoya-City (JP)

(21) Appl. No.: 14/490,748

(22) Filed: Sep. 19, 2014

(30) Foreign Application Priority Data
Sep. 24, 2013 (JP) 2013-197112

(51) Int. Cl. H01B 17/58; H01B 3/12; H01J 37/32

(52) U.S. Cl. CPC H01B 17/58; H01J 37/32532; H01J 37/32348; H01B 3/12
USPC 315/111.01; 174/68.3; 174/95

(57) ABSTRACT

A structural body is provided in fluid, perpendicular to a typical flow direction of the fluid. The structural body includes a cylindrical insulating body having at least one hollow portion and at least one conducting body positioned in the hollow portion of the insulating body. In a cross section of the insulating body having a normal line in an axial direction of the insulating body, the following relationship is satisfied:

1.5×Diy≦Dix≦15×Diy

where Dix is a length of the insulating body in the typical flow direction (direction x) and Diy is a maximum value of a length of the insulating body in a direction (direction y) perpendicular to the typical flow direction.

### CROSS-REFERENCE TO RELATED APPLICATION

This application is based upon and claims the benefit of priority from Japanese Patent Application No. 2013-197112 filed on Sep. 24, 2013, the contents of which are incorporated herein by reference.

### BACKGROUND OF THE INVENTION

1. Field of the Invention

The present invention relates to a structural body including an insulating body and a conductive material. For example, the present invention relates to a structural body and an electrode structure suitable for use, e.g., in a dielectric-barrier discharge electrode, an ozone generator, or the like.

2. Description of the Related Art

Heretofore, low-temperature plasma generators described, for example, in Japanese Patent No. 3015268 have been known as a structural body containing an insulating body and a conductive material.

Japanese Patent No. 3015268 describes an example of providing structure of one low-temperature plasma generator in the following manner. In particular, a rod-shaped ceramic dielectric body is inserted into a through hole of a rod-shaped ceramic dielectric body extending in the longitudinal direction. Both ends of the conductive body and the dielectric body are integrally joined and sealed with a glass or an inorganic or organic adhesive to form one electrode. A plurality of the electrodes are joined together by line-contact in the ceramic dielectric body. Potentials having different polarities are applied to the adjacent electrodes.

### SUMMARY OF THE INVENTION

However, in the plasma generator described in Japanese Patent No. 3015268, since the adjacent electrodes (to which potentials having different polarities are applied) are joined together by line-contact, supply of fluid such as the air into a space between the adjacent electrodes is not expected.

Further, with respect to the electric field distribution contributing to the ozone generation efficiency, the electric field is only generated at a recess having the bottom at the joined portion of surfaces of the adjacent electrodes (surfaces of rod shaped ceramic dielectric bodies). The area of the electric field is small in comparison with the electric field generated in a gap (space) between electrodes which face each other. Therefore, in the example of Japanese Patent No. 3015268, the efficient ozone generation cannot be expected.

That is, the above recess is narrow as an area to which oxygen molecules as the ozone raw material are supplied, and the electric field as an energy source of ozone generation cannot be provided efficiently.

In an attempt to address the problem, as a possible method to increase the amount of generated ozone, it is suggested to dispose a large number of electrodes that are joined together, and use thick electrodes to increase the effective volume for discharge of electricity (e.g., see FIG. 5 of Japanese Patent No, 3015268). However, in this method, the pressure loss is increased disadvantageously.

The present invention has been made to take the problems of this type into consideration, and an object of the present invention is to provide a structural body and an electrode structure in which when fluid passes through the structural body or bodies, the pressure loss in the fluid is reduced, and improvement in the ozone generation efficiency is achieved.

[1] According to a first aspect of the present invention, a structural body is provided in fluid, perpendicular to a typical flow direction of the fluid. The structural body includes a cylindrical insulating body having at least one hollow portion and at least one conducting body positioned in the hollow portion of the insulating body.

In a cross section of the insulating body having a normal line in an axial direction of the insulating body, a following relationship is satisfied:

1.5×Diy≦Dix≦15×Diy

where Dix is a length of the insulating body in the typical flow direction and Diy is a maximum value of a length of the insulating body in a direction perpendicular to the typical flow direction. Preferably, the relationship: 2.0×Diy≦Dix≦10×Diy is satisfied.
[2] In the structural body according to the first aspect of the present invention, in the cross section, a following relationship may be satisfied:

1.2×Dcy≦Dcx≦12×Dcy

where Dcx is a length of the conducting body in the typical flow direction and Dcy is a maximum value of a length of the conducting body in the direction perpendicular to the typical flow direction. Preferably, the relationship: 3.0×Dcy≦Dcx≦8.0×Dcy is satisfied.
[3] In this case, the insulating body may have a plurality of the hollow portions containing a plurality of the conducting bodies, respectively, and same potential may be applied to each of the conducting bodies.
[4] If a plurality of the conducting bodies are arranged in the typical flow direction, the Dcx represents a sum of lengths of the conducting bodies arranged in the typical flow direction.
[5] If a plurality of the conducting bodies are arranged in the direction perpendicular to the typical flow direction, and the Dcy represents a maximum value of lengths of the conducting bodies arranged in the direction perpendicular to the typical flow direction.
[6] Further, a following relationship may be satisfied:

1.1×Dmn/2≦Lmn≦2.0×Dmn/2

where Dmn is a sum of typical dimensions of at least a pair of adjacent conducting bodies among the plurality of the conducting bodies and Lmn is a distance between centers of the conducting bodies.
Preferably, the relationship: 1.1×Dmn/2≦Lmn≦1.5×Dmn/2 is satisfied.
[7] In the cross section, at least one of an upstream end and a downstream end of the insulating body with respect to flow of the fluid may have a shape where a length perpendicular to the typical flow direction is decreased gradually toward a front end of the insulating body.
[8] In this case, the at least one of the upstream end and the downstream end may include at least one tapered portion.
[9] Further, the front end may have a curved shape configured to satisfy the following relationship:

0.05×Diy≦2×Rt≦0.7×Diy

where Rt is a radius of curvature of the curved shape.
[10] In the structural body according to the first aspect of the present invention, the insulating body has an upstream end and a downstream end with respect to flow of the fluid, and at least the upstream end may have a shape where a length in a direction perpendicular to the typical flow direction and perpendicular to a longitudinal direction of the insulating body is decreased gradually toward a front end of the insulating body.
[11] In this case, the insulating body may include a front surface and a back surface extending in parallel to flow of the fluid, and the front surface may include a tapered surface at the upstream end of the insulating body and the back surface may include a flat surface at the upstream end of the insulating body.
[12] Alternatively, the front surface may include a flat surface at the upstream end of the insulating body and the back surface may include a tapered surface at the upstream end of the insulating body.
[13] Alternatively, the front surface may include a tapered surface at the upstream end of the insulating body and the back surface may include a tapered surface at the upstream end of the insulating body.
[14] In the structural body according to the first aspect of the present invention, the insulating body has an upstream end and a downstream end with respect to flow of the fluid, and at least the downstream end may have a shape where a length in a direction perpendicular to the typical flow direction and perpendicular to a longitudinal direction of the insulating body is decreased gradually toward a front end of the insulating body.
[15] In this case, the insulating body may include a front surface and a back surface extending in parallel to flow of the fluid, and the front surface may include a tapered surface at the downstream end of the insulating body and the back surface may include a flat surface at the downstream end of the insulating body.
[16] Alternatively, the front surface may include a flat surface at the downstream end of the insulating body and the back surface may include a tapered surface at the downstream end of the insulating body.
[17] Alternatively, the front surface may include a tapered surface at the downstream end of the insulating body and the back surface may include a tapered surface at the downstream end of the insulating body.
[18] In the structural body according to the first aspect of the present invention, the insulating body and the conducting body may be directly joined together integrally by firing.
[19] According to a second aspect of the present invention, a structural body includes a cylindrical insulating body having at least one hollow portion and at least one conducting body positioned in the hollow portion of the insulating body.

In a cross section of the insulating body having a normal line in an axial direction of the insulating body, a following relationship is satisfied:

1.5×Diy≦Dix≦15×Diy

where Dix is a length of the insulating body in a first direction, and Diy is a maximum value of a length of the insulating body in a second direction perpendicular to the first direction.

In the cross section, a following relationship is satisfied:

1.2×Dcy≦Dcx≦12×Dcy

where Dcx is a length of the conducting body in the first direction and Dcy is a maximum value of a length of the conducting body in the second direction.
[20] According to a third aspect of the present invention, an electrode structure has at least two structural bodies according to the first aspect or the second aspect of the present invention. Alternating current voltage is applied between the conducting body of one of the structural bodies and the conducting body of another of the structural bodies. The one of the structural bodies and the other of the structural bodies are arranged such that an axial direction of the insulating body is oriented in perpendicular to the typical flow direction.

In the structural body and the electrode structure according to the present invention, when fluid passes through the structural body or bodies, the pressure loss in the fluid is reduced, and improvement in the ozone generation efficiency is achieved.

The above and other objects, features, and advantages of the present invention will become more apparent from the following description when taken in conjunction with the accompanying drawings in which preferred embodiments of the present invention are shown by way of illustrative example.

### BRIEF DESCRIPTION OF THE DRAWINGS

FIG. 1A is a perspective view with partial omission showing a first structural body;

FIG. 1B is a perspective view with partial omission showing a first electrode structure;

FIG. 2A is a perspective view with partial omission showing a second structural body;

FIG. 2B is a perspective view with partial omission showing a second electrode structure;

FIG. 3A is a view showing an exemplary embodiment model of the second structural body and its operation;

FIG. 3B is a view showing an exemplary reference model and its operation;

FIG. 4 is a view showing cross sectional structure at both ends of an insulating body;

FIG. 5 is a flow chart showing a first production method of producing the first structural body and the second structural body;

FIG. 6A is a cross sectional view showing a green body prepared in a green body preparation step;

FIG. 6B is a cross sectional view showing a preliminarily-fired body prepared in a preliminarily fired body preparation step;

FIG. 6C is a cross sectional view showing a state where a bulk conducting body is inserted into a hollow portion of the preliminarily fired body in a conducting body insertion step;

FIG. 6D is a cross sectional view showing a structural body prepared in a firing/integration step;

FIG. 7 is a flow chart showing a second production method of producing the first structural body and the second structural body;

FIG. 8A is a cross sectional view showing a green body prepared in a green body preparation step;

FIG. 8B is a cross sectional view showing a state where a bulk conducting body is inserted into a hollow portion of the green body in a conducting body insertion step;

FIG. 8C is a cross sectional view showing a structural body prepared in a firing/integration step;

FIG. 9A is a cross sectional view showing a first modified example of the first structural body;

FIG. 9B is a cross sectional view showing a second modified example of the first structural body;

FIG. 9C is a cross sectional view showing a third modified example of the first structural body;

FIG. 9D is a cross sectional view showing a fourth modified example of the first structural body;

FIG. 10A is a cross sectional view showing a fifth modified example of the first structural body;

FIG. 10B is a cross sectional view showing a sixth modified example of the first structural body;

FIG. 11A is a cross sectional view showing a first modified example of the second structural body;

FIG. 11B is a cross sectional view showing a second modified example of the second structural body;

FIG. 11C is a cross sectional view showing a third modified example of the second structural body;

FIG. 11D is a cross sectional view showing a fourth modified example of the second structural body;

FIG. 12A is a cross sectional view showing a fifth modified example of the second structural body;

FIG. 12B is a cross sectional view showing a sixth modified example of the second structural body;

FIG. 12C is a cross sectional view showing a seventh modified example of the second structural body;

FIG. 12D is a cross sectional view showing an eighth modified example of the second structural body;

FIG. 13A is a cross sectional view showing a ninth modified example of the second structural body;

FIG. 13B is a cross sectional view showing a tenth modified example of the second structural body;

FIG. 13C is a cross sectional view showing an eleventh modified example of the second structural body;

FIG. 13D is a cross sectional view showing a twelfth modified example of the second structural body;

FIG. 14 is a cross sectional view showing a modified example of the first electrode structure;

FIG. 15A is a cross sectional view showing a first modified example of the second electrode structure;

FIG. 15B is a cross sectional view showing a second modified example of the second electrode structure;

FIG. 15C is a cross sectional view showing a third modified example of the second electrode structure;

FIG. 16A is a cross sectional view showing a fourth modified example of the second electrode structure;

FIG. 16B is a cross sectional view showing a fifth modified example of the second electrode structure;

FIG. 16C is a cross sectional view showing a sixth modified example of the second electrode structure; and

FIG. 17 is a cross sectional view showing structure of a pipe for checking pressure losses.

### DESCRIPTION OF THE PREFERRED EMBODIMENTS

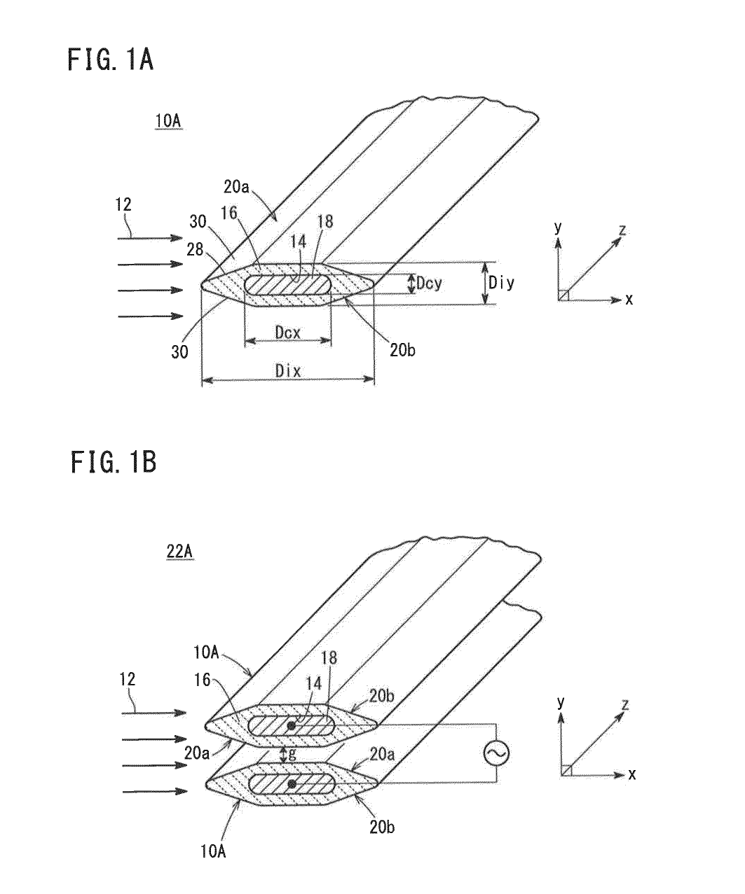

Hereinafter, embodiments of structural bodies and electrode structures according to the present invention will be described below with reference to FIGS. 1A to 17. It should be noted that, in this description, a numeric range of “A to B” includes both the numeric values A and B as the lower limit and upper limit values.

A structural body according to a first embodiment (hereinafter referred to as the “first structural body 10A”) is provided in fluid 12, in perpendicular to a typical flow direction of the fluid 12 (hereinafter referred to as the typical flow direction x), as can be seen from FIG. 1A showing main part of the first structural body 10A.

This first structural body 10A includes a tubular insulating body 16 having a hollow portion 14, and a conducting body 18 provided in the hollow portion 14 of the insulating body 16. The insulating body 16 has a front surface 20a and a back surface 20b as contact surfaces contacting the fluid 12. For example, the conducting body 18 has a track shape in cross section, including semi-circular curves at its both ends.

The typical flow direction x represents a flow direction at the central portion of the fluid 12 having directivity. This means that the flow direction in the peripheral part of the fluid 12 is not considered since the fluid 12 does not have any directivity in its peripheral part.

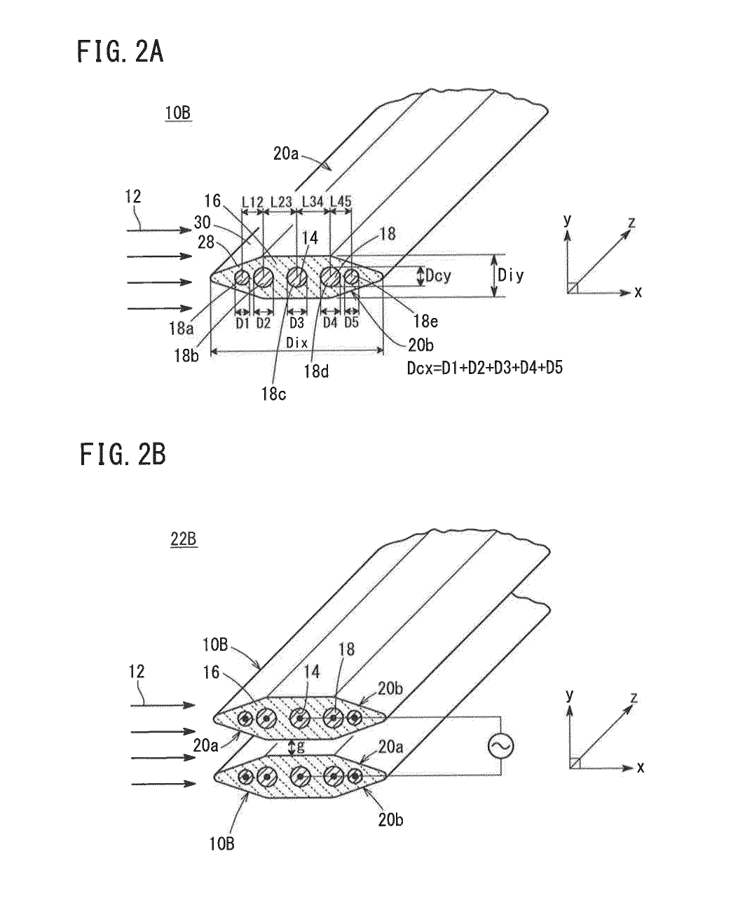

A structural body according to a second embodiment (hereinafter referred to as the “second structural body 10B) has substantially the same structure as the above described first structural body 10A, as can be seen from FIG. 2A showing main part of the second structural body 10B. However, the second structural body 10B is different from the first structural body 10A in that the insulating body 16 has a plurality of hollow portions 14 containing conducting bodies 18, respectively, and the same electric potential is applied to each of the conducting bodies 18. For example, each of the conducting bodies 18 has a circular shape in cross section. In an example of FIG. 2A, five hollow portions 14 are formed in the insulating body 16. These hollow portions 14 contain conducting bodies 18 (five conducting bodies 18), respectively. Among the five conducting bodies 18, a first conducting body 18a positioned at an upstream end of the insulating body 16 and a fifth conducting body 18e positioned at a downstream end of the insulating body 16 have diameters smaller than those of the other conducting bodies (second conducting bodies 18b to fourth conducting bodies 18d).

Further, the second structural body 10B satisfies the relationship: L12=L45, L23=L34, and L12<L23 where L12 is the distance between the center of the first conducting body 18a and the center of the second conducting body 18b, L23 is the distance between the center of the second conducting body 18b and the center of a third conducting body 18c, L34 is the distance between the center of the third conducting body 18c and the center of the fourth conducting body 18d, and L45 is the distance between the center of the fourth conducting body 18d and the center of the fifth conducting body 18e. This relationship is merely a non-restrictive example.

In the case of using the first structural body 10A and the second structural body 10B as an electrode structure or the like, the insulating body 16 may be referred to as the dielectric body for inducing charges.

In particular, in the cross section having a normal line in the axial direction z of the insulating body 16, the embodiment of the present invention satisfies the following relationship:

1.5×Diy≦Dix≦15×Diy

where Dix is the length of the insulating body 16 in the typical flow direction x and Diy is the maximum value of the length of the insulating body 16 in the direction y perpendicular to the typical flow direction x.

In the structure, since the outer shapes of the first structural body 10A and the second structural body 10B are narrow and long with respect to the typical flow direction x, the pressure loss can be reduced.

In this regard, in the case where the fluid 12 is used for generating ozone, for example, a raw gas containing air and oxygen may be used.

The material for the insulating body 16 may include a single oxide, a single nitride, a composite oxide or a composite nitride material containing one or more substances selected from the group consisting of barium oxide, bismuth oxide, titanium oxide, zinc oxide, neodymium oxide, titanium nitride, aluminum nitride, silicon nitride, alumina, silica, and mullite.

The conducting body 18 is preferably made of a material containing a substance selected from the group consisting of molybdenum, tungsten, silver, copper, nickel, and alloys containing at least one of these substances. Examples of such alloys include instar, kovar, inconel (registered trademark), incoloy (registered trademark).

The insulating body 16 is preferably made of a ceramic material such as LTCC (Low Temperature Co-fired Ceramics), which can be fired at a temperature lower than the melting point of the conducting body 18. Specifically, the material for the insulating body 16 preferably includes a single oxide, a single nitride, a composite oxide or a composite nitride material containing one or more substances selected from the group consisting of barium oxide, bismuth oxide, titanium oxide, zinc oxide, neodymium oxide, titanium nitride, aluminum nitride, silicon nitride, alumina, silica, and mullite.

Further, in an electrode structure according to the first embodiment using the first structural bodies 10A (hereinafter referred to as the “first electrode structure 22A”), as shown in FIG. 1B, alternating current voltage is applied to the conducting body 18 of one of the first structural bodies 10A and the conducting body 18 of the other of the first structural bodies 10A. In each of the one of the first structural bodies 10A and the other of the first structural bodies 10A, the axial direction z of the insulating body 16 is perpendicular to the typical flow direction x. In an example of FIG. 1B, a gap g is formed between front surfaces 20a of the first structural bodies 10A that face each other. It is a matter of course that the back surfaces 20b of the first structural bodies 10A may face each other, or the front surface 20a of one of the first structural bodies 10A and the back surface 20b of the other of the first structural bodies 10A may face each other.

Likewise, in an electrode structure according to the second embodiment using the second structural bodies 10B (hereinafter referred to as the “second electrode structure 22B”), as shown in FIG. 2B, alternating current voltage is applied between the conducting body 18 of one of the second structural bodies 10B and the conducting body 18 of the other of the second structural bodies 103. In each of the one of the second structural bodies 10B and the other of the second structural bodies 10B, the axial direction z of the insulating body 16 is perpendicular to the typical flow direction x. In an example of FIG. 2B, a gap is formed between front surfaces 20a of the second structural bodies 10B that face each other. It is a matter of course that the back surfaces 20b of the second structural bodies 10B may face each other, or the front surface 20a of one of the second structural bodies 103 and the back surface 20b of the other of the second structural bodies 10B may face each other.

Further, the first structural body 10A and the second structural body 10B satisfy the following relationship:

1.2×Dcy≦Dcx≦12×Dcy

where Dcx is the length of the conducting body 18 in the typical flow direction x and Dcy is the maximum value of the length of the conducting body 18 in the direction y perpendicular to the typical flow direction x as shown in FIG. 1A and FIG. 2A.

In this regard, as shown in FIG. 1A, in the first structural body 10A, the length Dcx represents the maximum value of the conducting body 18 in the typical flow direction x (in this case, the length of the segment in the direction of the central line). As shown in FIG. 2A, in the second structural body 10B, the length Dcx represents the sum of the maximum values of the lengths of the respective conducting bodies 18 in the typical flow direction x (in this case, the diameters of the conducting bodies 18). In the first structural body 10A, the maximum value Dcy of the length represents the maximum value of the length of the conducting body 18 in the direction y perpendicular to the typical flow direction x (in this case, the length of the segment in the direction perpendicular to the central line). In the second structural body 10B, the maximum value Dcy of the length represents the longest dimension among the lengths of the conducting bodies 18 in the direction y perpendicular to the typical flow direction x (in this case, the diameter of the conducting body 18).

In the structure, in the first structural body 10A, one long and narrow conducting body 18 can be provided in the typical flow direction x. In the second structural body 10B, a plurality of conducting bodies 18 can be provided in the typical flow direction x. Therefore, by adopting any of the first electrode structure 22A and the second electrode structure 22B, an electrical field can be generated in a planar wide space between the surfaces 20a. Thus, improvement in the ozone generation efficiency is achieved.

In particular, the second structural body 10B satisfies the following relationship:

1.1×Dmn/2≦Lmn≦2.0×Dmn/2

where Dmn is the sum of the typical dimensions of at least a pair of adjacent conducting bodies 18 among the plurality of conducting bodies 18 and Lmn is the distance between the centers of the conducting bodies 18 as shown in FIG. 2A.

The typical dimensions of at least a pair of adjacent conducting bodies 18 means the respective maximum values of the lengths of the conducting bodies 18 arranged in the typical flow direction x (in this case, the diameters of the conducting bodies 18).

In this regard, as an example, the adjacent first conducting body 18a and second conducting body 18b, and the adjacent second conducting body 18b and third conducting body 18c will be considered. The following relationship is present between the sum D12 of the typical dimension D1 of the first conducting body 18a and the typical dimension D2 of the second conducting body 18b and the distance L12 between the center of the first conducting body 18a and the center of the second conducting body 18b.

1.1×D12/2≦L12≦2.0×D12/2

Likewise, the following relationship is present between the sum D23 of the typical dimension D2 of the second conducting body 18b and the typical dimension D3 of the third conducting body 18c and the distance L23 between the center of the second conducting body 18b and the center of the third conducting body 18c.

1.1×D23/2≦L23≦2.0×D23/2

The similar relationship is present among the other conducting bodies.

In the structure, the adjacent conducting bodies 18 can be provided closely to each other. Therefore, by adopting the second electrode structure 22B, an electric field can be generated in a planar wide space between the surfaces 20a. Thus, improvement in the ozone generation efficiency achieved.

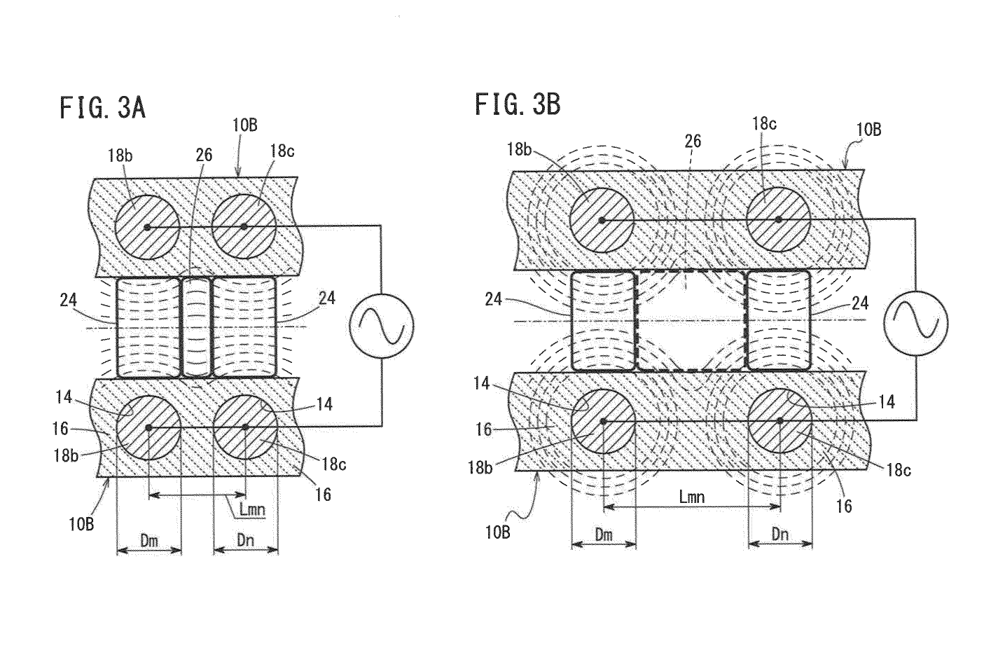

Next, based on an exemplary embodiment model and an exemplary reference model of the second structural bodies 10B, the space where the electric field is generated will be considered with reference to FIGS. 3A and 3B. It should be noted that FIGS. 3A and 3B mainly show parts of second structural bodies 10B where the conducting bodies 18b and 18c are present (see FIG. 2A). Further, in FIGS. 3A and 3B, though contour lines are smoothly connected at the border between the space and the dielectric body, in reality, the contour lines are bent at this border since the space and the dielectric body have different dielectric constants.

Firstly, in the exemplary model of the second structural bodies 10B, as shown in FIG. 3A, the sum Dmn (=Dm+Dn) of the typical dimensions of the adjacent conducting bodies 18 and the distance Lmn between the centers of the respective conducting bodies 18 were determined to satisfy the relationship as shown in the above formula. Further, alternating current voltage was applied between the conducting body 18 of one of the second structural bodies 10B and the conducting body 18 of the other of the second structural bodies 10B to generate an electric field in a space between these second structural bodies 10B facing each other.

In the exemplary reference model, as shown in FIG. 33, two pairs of conducting bodies 18 were prepared. Each pair includes two conducting bodies 18 spaced from each other. The sum Dmn of the typical dimensions of the adjacent conducting bodies 18 and the distance Lmn between the centers of the respective conducting bodies 18 are determined not to satisfy the relationship as shown in the above formula. Further, alternating current voltage was applied between the conducting body 18 of one of the second structural bodies 10B and the conducting body 18 of the other of the second structural bodies 10B to generate an electric field in a space between these second structural bodies 10B facing each other.

In the exemplary embodiment model of the second structural bodies 10B, the conducting bodies 18 are provided closely to each other. In the structure, the distance between an effective space 24 where the electric field is generated between one pair of the two conducting bodies 18b (effective space where the electric field is generated for ozone generation) and an effective space 24 where the electric field is generated between the other pair of the two conducting bodies 18c is small. As a result, a space 26 between these two effective spaces 24 also functioned as an effective space, and the electric field was effectively generated in a planar wide area as a whole.

In contrast, in the exemplary reference model, the conducting bodies 18 are provided remotely from each other in each of the second structural bodies 10B. In the structure, the distance between an effective space 24 where the electric field is generated between one pair of the two conducting bodies 18b and an effective space 24 where the electric field is generated between the other pair of the two conducting bodies 18c is long. Consequently, the electric field generated in the space 26 between these two effective spaces 24 is weak. That is, the space 26 did not function like the effective spaces 24, and the effective electric field was generated in each of the effective spaces 24 locally.

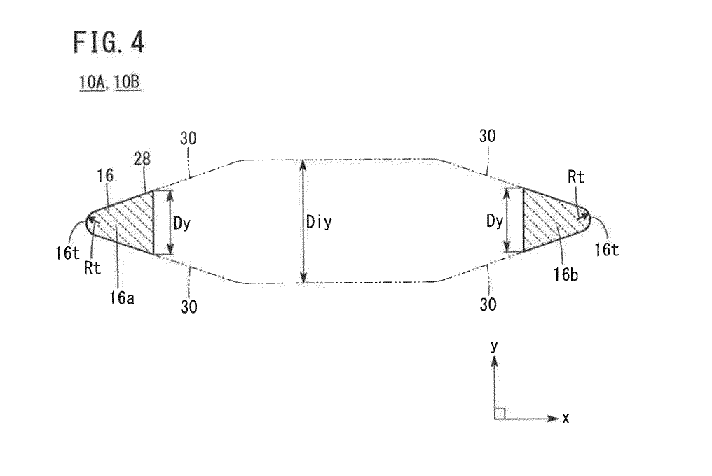

Further, as show in FIG. 4, the first structural body 10A and the second structural body 10B are configured to have a shape where at least at one of both ends of the insulating body 16, i.e., at least at one of the upstream end 16a and the downstream end 16b with respect to the flow of the fluid 12, the length Dy perpendicular to the typical flow direction x is gradually reduced toward a front end 16t. In this regard, preferably, at least one of the ends 16a, 16b includes at least one tapered portion 28. In this structure, the pressure loss can be reduced efficiently. For example, both of the first structural body 10A and the second structural body 10B have tapered surfaces 30 at upstream ends of the front surface 20a and the back surface 20b, and have tapered surfaces 30 at their downstream ends of the front surface 20a and the back surface 20b.

In particular, by configuring the front end 16t of the insulating body 16 to have a curved shape which satisfies the relationship

0.05×Diy≦2×Rt≦0.7×Diy

where Rt is the radius of curvature of the curved front end 16t, the pressure loss can be reduced significantly.

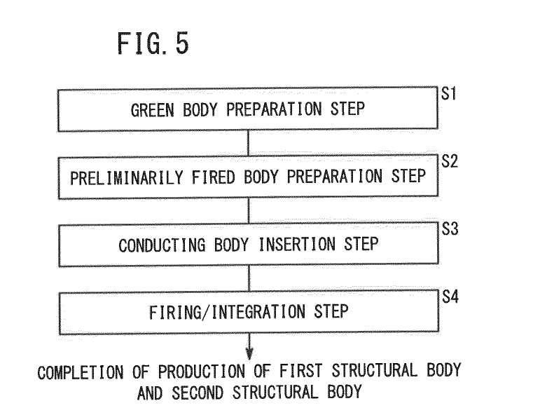

Next, two methods of producing the first structural body 10A and the second structural body 10B (a first production method and a second production method) will be described with reference to FIGS. 5 to 8C.

### [First Production Method]

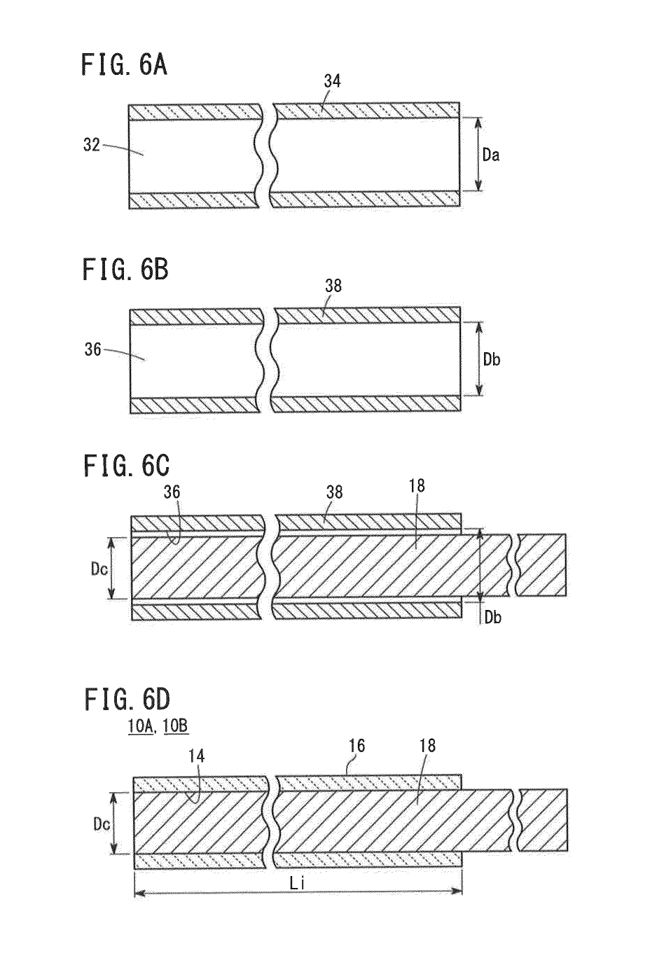

As shown in FIGS. 5 to 6D, the first production method of producing the first structural body 10A and the second structural body 10B includes a green-body preparation step S1 of preparing a green body 34 having a hollow portion 32, to be formed into the insulating body 16 (see FIG. 6A), a preliminarily-fired body preparation step S2 of degreasing and preliminary-firing the green body 34 to prepare a preliminarily-fired body 38 having a hollow portion 36 (see FIG. 6B), a conducting body insertion step S3 of inserting a bulk body of the conducting body 18 into the hollow portion 36 in the preliminarily-fired body 38, and a firing/integration step S4 of firing the preliminarily-fired body 38 together with the conducting body 18 inserted into the hollow portion 36 to produce the first structural body 10A and the second structural body 10B (see FIG. 6D).

In the green-body preparation step S1, a starting material slurry is shaped and solidified to prepare the green body. The starting material slurry contains a starting material powder, a dispersion medium, and an organic binder. In addition, the starting material slurry may contain a dispersion aid and a catalyst, as necessary. Specifically, the starting material powder may be a powder of a ceramic containing one or more elements selected from the group consisting of barium, bismuth, titanium, zinc, aluminum, silicon, magnesium, and neodymium. The dispersion medium may be a mixture of an aliphatic polyhydric ester and a polybasic acid ester, or ethylene glycol. The organic binder may be a gelling agent or the like. In a case where the green body 34 has, for example, an extruded shape with the hollow portion 32 (through-hole) as shown in FIG. 6A, the organic binder may be a substance other than the gelling agent (i.e., a substance that is hardened not by a chemical reaction but only by drying), etc. Of course, in a case where the green body 34 has a shape other than the extruded shape, the gelling agent should preferably be used. In this case, the gelling agent may include a substance that is hardened by a hardening reaction (a chemical reaction such as a urethane reaction). For example, the gelling agent may include a combination of a modified polymethylene polyphenyl polyisocyanate and a polyol. The dispersion medium may be a mixture of a dibasic acid ester. The dispersion aid may be a polycarboxylic acid-based copolymer. The catalyst may be a tertiary amine, and specific examples of the catalyst include 6-dimethylamino-1-hexanol or the like.

For example, in the case of preparing the green body 34 having the extruded shape with the through-hole being formed as the hollow portion 32, the starting material slurry can be preferably shaped by extrusion molding. The inner diameter Da of the hollow portion 32 in the green body 34 is slightly larger than the outer diameter Dc of the conducting body 18. Therefore, the conducting body 18 can be easily inserted into the hollow portion 32.

In the case of using the extrusion molding, a long body extruded from an extruder is cut into the green bodies 34 having a predetermined length, and successively the green bodies 34 are degreased and preliminarily-fired. Alternatively, a long body extruded from the extruder is cut into the green bodies 34 having a predetermined length while being degreased and preliminarily-fired. Therefore, the steps can be continuously carried out to improve the productivity.

Of course, in the case of using the gelling agent in the organic binder, the starting material slurry may be shaped by using a mold having a molding cavity corresponding to the tubular insulating body 16. In this case, the molding cavity of the mold is filled with the starting material slurry. The starting material slurry is molded into a shape corresponding to the tubular shape of the insulating body 16. The molded starting material slurry is solidified via the hardening reaction of the gelling agent. The solidified slurry is separated (demolded) from the mold, and then degreased and preliminarily-fired. This process performed by molding the starting material slurry including the starting material powder, the dispersion medium, and the gelling agent, and solidifying the molded slurry via the hardening reaction of the gelling agent to prepare the green body 34, is known as “a gel casting process”.

In the preliminarily-fired body preparation step S2, firstly, the shaped green body 34 is degreased and then preliminarily-fired. The degreasing is a treatment for burning to remove an organic component such as a binder from the green body 34. The green body 34 becomes brittle temporarily by the removal of the binder. The preliminary-firing is a treatment for sintering the brittle green body 34 to some extent to obtain the preliminarily-fired body 38 that is strong enough to handle. It should be noted that the preliminarily-fired body 38 is not brought into a sufficiently-sintered state, and significant firing shrinkage does not occur. More specifically, for example, the green body 34 is preliminarily-fired in an air atmosphere at a temperature of 400° C. to 800° C. for 1 to 8 hours. In view of handling in the following step, the temperature is increased until the firing treatment proceeds to such an extent that the green body 34 can have a sufficient strength (i.e., the preliminarily-fired body 38 is obtained). As described above, the preliminarily-fired body 38 is not significantly shrunk by sintering in this step. Therefore, the inner diameter Db of the hollow portion 36 in the preliminarily-fired body 38 is approximately equal to the inner diameter Da of the hollow portion 32 in the green body 34, and the conducting body 18 can be easily inserted into the hollow portion 32.

In the conducting body insertion step S3, as shown in FIG. 6C, the solid conducting body 18 itself is inserted into the hollow portion 36 in the preliminarily-fired body 38 obtained in the manner as described above. Though the conducting body 18 is placed at the center of the hollow portion 36 in FIG. 6C, it is a matter of course that the conducting body 18 may partially contact the inner wall surface of the hollow portion 36 during or after the process of inserting the conducting body 18.

The preliminarily-fired body 38 has a stiffness property. Therefore, the conducting body 18 can be easily inserted into the hollow portion 36 in the preliminarily-fired body 38, and the preliminarily-fired body 38 can be easily handled. Thus, the conducting body 18 can be automatically inserted using a robot or the like or during transportation of the preliminarily-fired body 38. For example, the conducting body 18 may be a cylindrical solid made of a metal or cermet material containing molybdenum or a molybdenum alloy. In the following firing step, the preliminarily-fired body 38 is subjected to firing shrinkage, and the conducting body 18 is not shrunk by the firing. Thus, the outer diameter Dc of the conducting body 18 is determined to be smaller than the inner diameter Db of the hollow portion 36 (through-hole) in the preliminarily fired body 38 (see FIG. 6C) by the amount of the firing shrinkage of the preliminarily-fired body 38. By determining the outer diameter Do of the conducting body 18 to be slightly larger than the inner diameter of the green body 34 when it is fired alone, specifically, by a dimension which is larger than 0 μm, and equal to or less than 10 μm, the conducting body 18 and the green body 34 can be tightly adhered together, and combined integrally.

In the firing/integration step S4, the preliminarily-fired body 38 is fired together with the conducting body 18 inserted into the preliminarily-fired body 38. For example, the firing is carried out in an oxygen-free atmosphere (such as a nitrogen or argon atmosphere). The oxygen-free atmosphere is not limited to an atmosphere completely free from oxygen, and may be, for example, the following atmosphere (a) or (b):

(a) an atmosphere provided by introducing nitrogen or argon into a firing furnace, while discharging air from the firing furnace, to replace the air by the nitrogen or argon; or
(b) an atmosphere provided by introducing nitrogen or argon into the firing furnace after vacuating the firing furnace.

In the firing/integration step, the firing temperature is 900° C. to 1600° C., preferably 900° C. to 1050° C. When the firing temperature is within the preferred temperature range, material for the conducting body can be chosen from a wide variety of materials. For example, in the case of using an alumina as the material for the insulating body, the upper limit of the firing temperature is 1600° C. The firing time is 1 to 10 hours.

The firing treatment may be carried out while maintaining an atmosphere containing a small amount of oxygen. However, in the case of performing the firing in the oxygen-free atmosphere as described above, it is not necessary to control the atmosphere containing a small amount of oxygen, and the insulating body 16 can be easily sintered while oxidation of the conducting body 18 is prevented.

The preliminarily-fired body 38 is shrunk by the firing. As a result, a so-called shrinkage fitting of the conducting body 18 is achieved. Thus, the fired insulating body 16 and the conducting body 18 are firmly joined together integrally. Consequently, the first structural body 10A and the second structural body 10B, which contain the insulating body 16 and the conducting body 18 embedded in the hollow portion 14 of the insulating body 16, is produced.

It should be noted that an intermediate layer containing main components of the conducting body 18 (e.g., molybdenum) may be formed at the border portion between the insulating body 16 and the conducting body 18. This intermediate layer is formed by diffusion of the main components of the conducting body 18 into the insulating body 16 at the time of firing. Further, no pores having the size of 50 μm or more are formed in the insulating body 16 covering the conducting body 18. If the insulating body 16 has a large porosity expressed in the order of percentage, dielectric breakdown may occur easily due to the voltage applied to ceramics. In the presence of only one closed pore having the size of 50 μm in the insulating body 16 as a whole, dielectric breakdown may occur from the portion of the closed pore to cause arc plasma, and to cause dissolution of ceramics. Ideally, no closed pore should be present. It is desirable that diameters of all of the closed pores dispersed in the material are less than 10 μm.

### [Second Production Method]

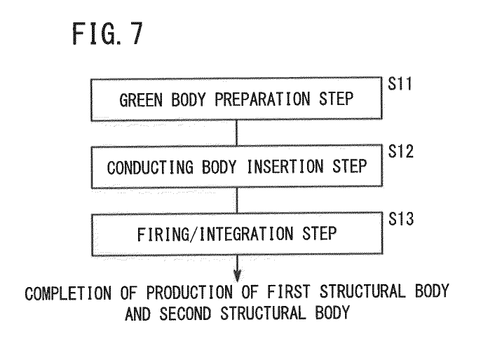

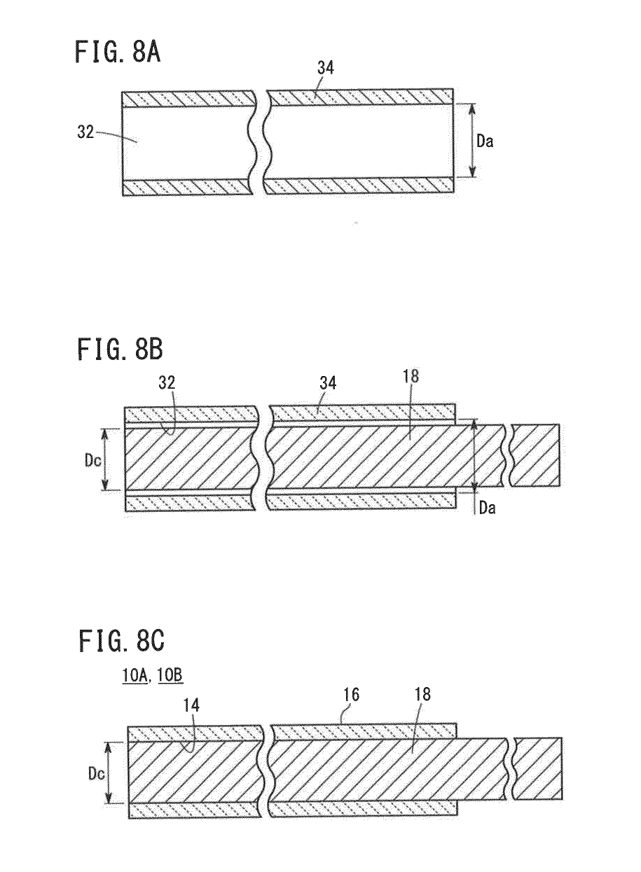

As shown in FIGS. 7 to 8C, the second production method of producing the first structural body 10A and the second structural body 105 includes a green-body preparation step S11 of preparing a green body 34 having a hollow portion 32, to be formed into the insulating body 16 (see FIG. 8A), a conducting body insertion step S12 of inserting a bulk body of the conducting body 18 into the hollow portion 32 in the green body 34, and a firing/integration step S13 of firing the green body 34 together with the conducting body 18 inserted into the hollow portion 32 to produce the first structural body 10A and the second structural body 105.

In the green-body preparation step S11, the starting material slurry is shaped and solidified to prepare the green body 34 shown in FIG. 8A in the same manner as the green-body preparation step S1 in the first production method.

In the conducting body insertion step S12, as shown in FIG. 8B, the solid conducting body 18 itself is inserted into the hollow portion 32 in the green body 34 obtained in the manner as described above. Though the conducting body 18 is placed at the center of the hollow portion 32 in FIG. 8B, the conducting body 18 may partially contact the inner wall surface of the hollow portion 32 during or after the process of inserting the conducting body 18. In the following firing step, the green body 34 is subjected to firing shrinkage, while the conducting body 18 is not shrunk by the firing. Thus, the outer diameter Dc of the conducting body 18 is determined to be smaller than the inner diameter Da of the hollow portion 32 (through-hole) in the green body 34 by the amount of the firing shrinkage of the green body 34. By determining the outer diameter Dc of the conducting body 18 to be slightly larger than the inner diameter of the green body 34 when it is fired alone, specifically, by a dimension which is larger than 0 μm, and equal to or less than 10 μm, the conducting body 18 and the green body 34 can be tightly adhered together, and combined integrally.

In the firing/integration step S13, the green body 34 is fired together with the conducting body 18 inserted into the green body 34. For example, the firing is carried out in a weakly oxidizing atmosphere containing an inert gas such as a humidified nitrogen or argon gas (an atmosphere having a low oxygen partial pressure) at a temperature of 900° C. to 1600° C. (preferably 900° C. to 1050° C.) for 1 to 20 hours. The humidification is achieved by bubbling of the inert gas in water having a temperature of 10° C. to 80° C. The firing is carried out in the weakly oxidizing atmosphere for the following reasons:

(1) a certain level of oxidizing atmosphere is required for firing and removing the gelling agent; and
(2) the oxygen partial pressure in the oxidizing atmosphere is required to be small in order to prevent excess oxidation of the conducting body 18.

In the above firing, the green body 34 is subjected to firing shrinkage. As a result, a so-called shrinkage fitting of the conducting body 18 is achieved. Thus, the fired insulating body 16 and the conducting body 18 are firmly joined together.

In the first and second production methods described above, in the case of using the gel casting process in the green-body preparation steps S1 and S11, a submicron starting material powder can be used and significantly uniformly distributed in the green body 34. Therefore, the firing shrinkage ratio can be highly accurately controlled, and a dense sintered body (the insulating body 16) can be prepared without defects. The denseness is effective in improving the voltage resistance of the electrode.

As for the method of preparing the first structural body 10A and the second structural body 10B, instead of adopting the above method, in a possible method, the conducting body 18 and the insulating body 16 are prepared separately, and after the conducting body 18 is inserted into the hollow portion 14 of the insulating body 16, these components are adhered together using resin or the like. Alternatively, conducting body paste may fill the hollow portion 14 of the insulating body 16. In the former method, the desired durability cannot be expected at high temperature in terms of heat resistance of resin. In the latter method, it is difficult to form a dense conducting body, and abnormal electrical discharge tends to occur easily.

Therefore, as in the cases of the first production method and the second production method described above, it is preferable to insert one or more conducting bodies 18 into hollow portions 36 of the preliminarily-fired body 38, and thereafter, fire the preliminarily-fired body 38 and the conducting body 18 to directly join these components integrally.

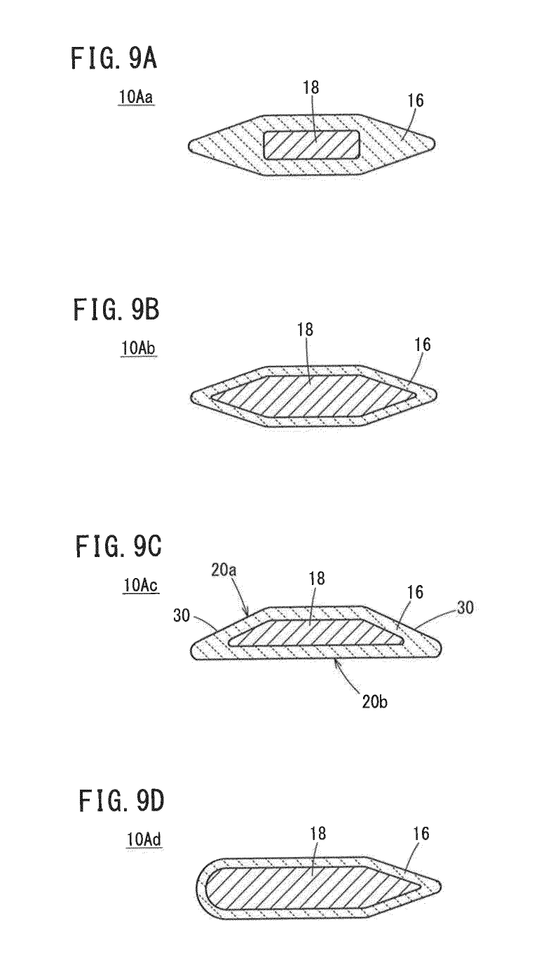

Next, modified examples of the first structural body 10A will be described with reference to FIGS. 9A to 103.

As shown in FIG. 9A, a first modified example (10Aa) of the first structural body 10A is different from the first structural body 10A in that the conducting body 18 has, e.g., a rectangular shape in cross section, and has a curved shape at its corner portions.

As shown in FIG. 9B, a second modified example (10Ab) of the first structural body 10A is different from the first structural body 10A in that the cross sectional shape, in particular, the outer shape of the conducting body 18 is similar to the outer shape of the insulating body 16.

As shown in FIG. 9C, a third modified example (10Ac) of the first structural body 10A is different from the first structural body 10A in that the front surface 20a of the insulating body 16 includes tapered surfaces 30 at the upstream end and the downstream end, the back surface 20b of the insulating body 16 is a flat surface, and the conducting body 18 has a trapezoidal shape.

As shown in FIG. 9D, a fourth modified example (10Ad) of the first structural body 10A is different from the first structural body 10A in that the upstream end of the insulating body 16 has a circular shape, and the upstream end of the conducting body 18 also has a circular shape.

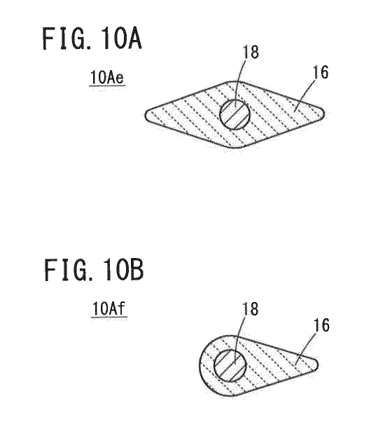

As shown in FIG. 10A, a fifth modified example (10Ae) of the first structural body 10A is different from the first structural body 10A in that the conducting body 18 has a circular shape in cross section.

As shown in FIG. 10B, a sixth modified example (10Af) of the first structural body 10A is different from the first structural body 10A in that the conducting body 18 has a circular shape in cross section, and the upstream end of the insulating body 16 has a circular shape.

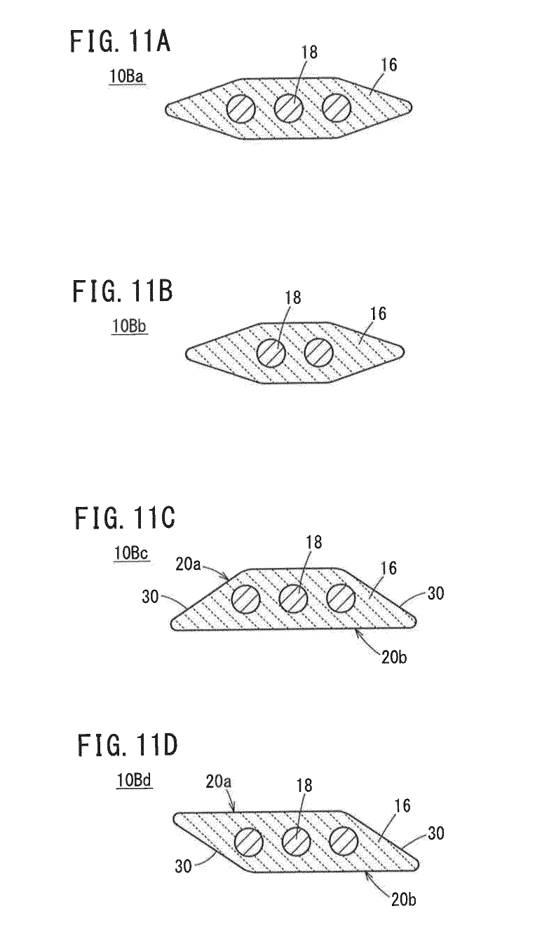

Next, modified examples of the second structural body 10B will be described with reference to FIGS. 11A to 13D.

As shown in FIG. 11A, a first modified example (10Ba) of the second structural body 10B is different from the second structural body 10B in that no conducting bodies 18 are present at the upstream end and the downstream end, and three conducting bodies 18 are present at the central portion.

As shown in FIG. 11B, a second modified example (10Bb) of the second structural body 10B is different from the first modified example (10Ba) in that two conducting bodies 18 are present at the central portion of the insulating body 16.

As shown in FIG. 11C, a third modified example (10Bc) of the second structural body 10B is different from the first modified example (10Ba) in that the front surface 20a of the insulating body 16 includes tapered surfaces 30 at the upstream end and the downstream end, and the back surface 20b of the insulating body 16 is a flat surface.

As shown in FIG. 11D, a fourth modified example (10Bd) of the second structural body 10B is different from the first modified example (10Ba) in that the front surface 20a of the insulating body 16 includes a tapered surface 30 at its downstream end, and the back surface 20b of the insulating body 16 includes a tapered surface 30 at its upstream end.

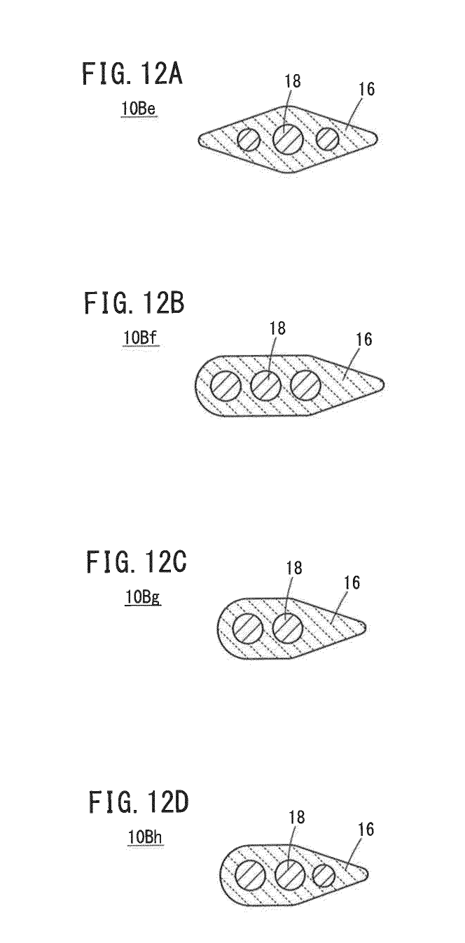

As shown in FIG. 12A, a fifth modified example (10Be) of the second structural body 10B is different from the second structural body 10B in that three conducting bodies 18 are present in the insulating body 16.

As shown in FIG. 12B, a sixth modified example (10Bf) of the second structural body 10B is different from the first modified example (10Ba) in that the upstream end of the insulating body 16 has a circular shape.

As shown in FIG. 12C, a seventh modified example (10Bg) of the second structural body 10B is different from the sixth modified example (10Bf) in that two conducting bodies 18 are present in the insulating body 16.

As shown in FIG. 12D, an eighth modified example (10Bh) of the second structural body 10B is different from the seventh modified example (10Bg) in that one conducting body 18 having a small diameter is positioned at the downstream end of the insulating body 16.

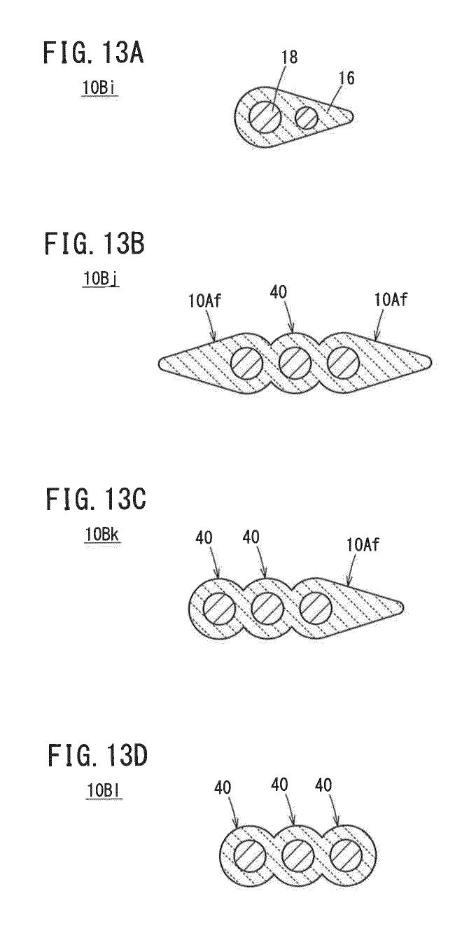

As shown in FIG. 13A, a ninth modified example (10Bi) of the second structural body 10B is different from the eighth modified example (10Bh) in that one conducting body 18 having a large diameter and one conducting body 18 having a small diameter are present.

As shown in FIG. 13B, a tenth modified example (10Bj) of the second structural body 10B is different from the second structural body 10B in that a structural body of an insulating body 16 having a circular outer shape (hereafter referred to as the “circular structural body 40”) is provided at the center, and the sixth modified example (10Af) of the first structural body 10A is provided on each of the left side and right side, i.e., on each of the upstream side and the downstream side of the circular structural body 40 in a symmetrical manner.

As shown in FIG. 13C, an eleventh modified example (10Bk) of the second structural body 10B is different from the second structural body 10B in that another circular structural body 40 is provided on the upstream side of the circular structural body 40, and the sixth modified example (10Af) of the first structural body 10A is provided on the downstream side of the circular structural body 40.

As shown in FIG. 13D, a twelfth modified example (10Bl) of the second structural body 10B is different from the second structural body 10B in that additional circular structural bodies 40 are provided on the upstream side and on the downstream side of the circular structural body 40, respectively.

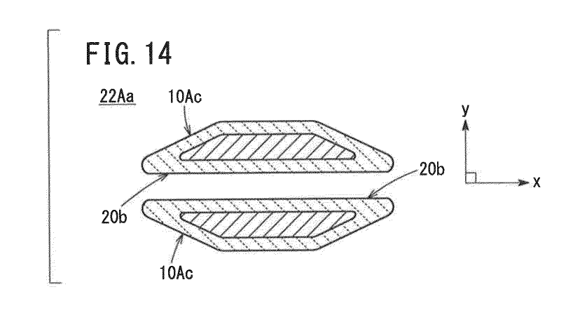

Next, a modified example of the first electrode structure 22A will be described with reference to FIG. 14.

As shown in FIG. 14, a modified example (22Aa) of the first electrode structure 22A is different from the first electrode structure 22A in that two structural bodies 10Ac of the third modified example of the first structural body 10A (see FIG. 9C) are arranged in a linearly symmetrical manner with respect to the typical flow direction x. In the example of FIG. 14, the back surfaces 20b of the structural bodies 10Ac of the third modified example face each other. It is a matter of course that front surfaces 20a of the structural bodies 10Ac of the third modified example may face each other, or the front surface 20a of one of the structural bodies 10Ac of the third modified example and the back surface 20b of another of the structural bodies 10Ac of the third modified example may face each other.

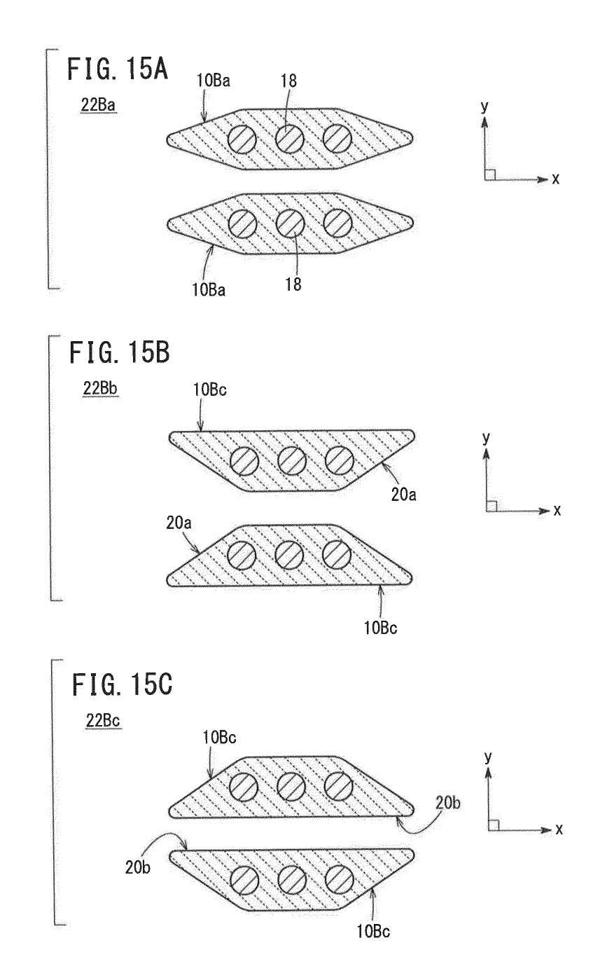

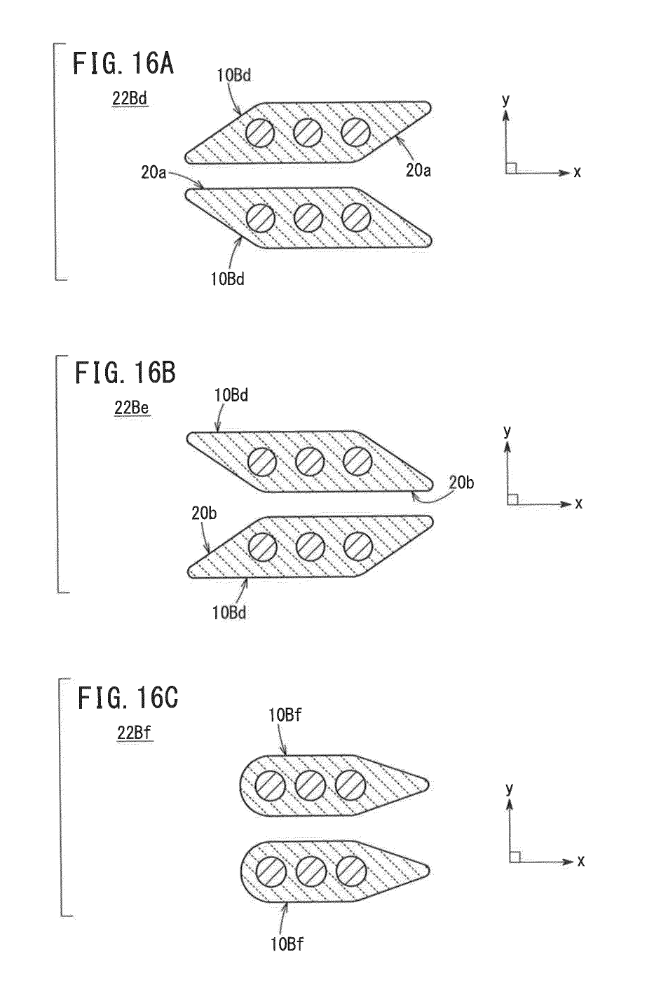

Next, modified examples of the second electrode structure 22B will be described with reference to FIGS. 15A to 16C.

As shown in FIG. 15A, a first modified example (22Ba) of the second electrode structure 22B is different from the second electrode structure 22B in that two structural bodies 10Ba of the first modified example of the second structural body 10B (see FIG. 11A) are arranged in a linearly symmetrical manner with respect to the typical flow direction x.

As shown in FIG. 15B, a second modified example (22Bb) of the second electrode structure 22B is different from the second electrode structure 22B in that two structural bodies 10Bc of the third modified example of the second structural body 10B (see FIG. 11C) are arranged in a linearly symmetrical manner with respect to the typical flow direction x. In the example of FIG. 15B, the front surfaces 20a of the structural bodies 10Bc of the third modified example face each other.

As shown in FIG. 15C, a third modified example (22Bc) of the second electrode structure 22B is different from the second modified example (22Bb) in that the back surfaces (20b) face each other.

As shown in FIG. 16A, a fourth modified example (22Bd) of the second electrode structure 22B is different from the second electrode structure 22B in that two structural bodies 10Bd of the fourth modified example of the second structural body 10B (see FIG. 11D) are arranged in a linearly symmetrical manner with respect to the typical flow direction x. In the example of FIG. 16A, the front surfaces 20a of the structural bodies 10Bd of the fourth modified example face each other.

As shown in FIG. 16B, a fifth modified example (22Be) of the second electrode structure 22B is different from the fourth modified example (22Bd) in that the back surfaces (2Db) face each other.

As shown in FIG. 16C, a sixth modified example (22Bf) of the second electrode structure 22B is different from the second electrode structure 22B in that two structural bodies 10Bf of the sixth modified example of the second structural body 10B (see FIG. 12B) are arranged in a linearly symmetrical manner with respect to the typical flow direction x.

Among these examples, in the first electrode structure 22A, the second electrode structure 22B, and the first modified example (22Ba), the second modified example (22Bb), the fifth modified example (22Be), and the sixth modified example (22Bf) of the second electrode structure 22B, the structural bodies (10A, 10B) have the tapered surfaces 30 facing each other at their upstream ends. In the structure, the gas is guided along the tapered surfaces 30 to move into the gap between the structural bodies (10A, 10B) easily. That is, the gas can be supplied into the gap between the structural bodies (10A, 10B) efficiently. Thus, improvement in the ozone generation efficiency is achieved.

Though the first electrode structure 22A, the second electrode structure 22B, and their modified examples have been described in connection with the cases where the same type of the structural bodies are arranged to face each other, different types of structural bodies may be provided to face each other.

### First Embodiment

The pressure losses in the structural bodies according to embodiments 1 to 6 and a comparative example 1 were checked.

### (Method of Checking Pressure Losses)

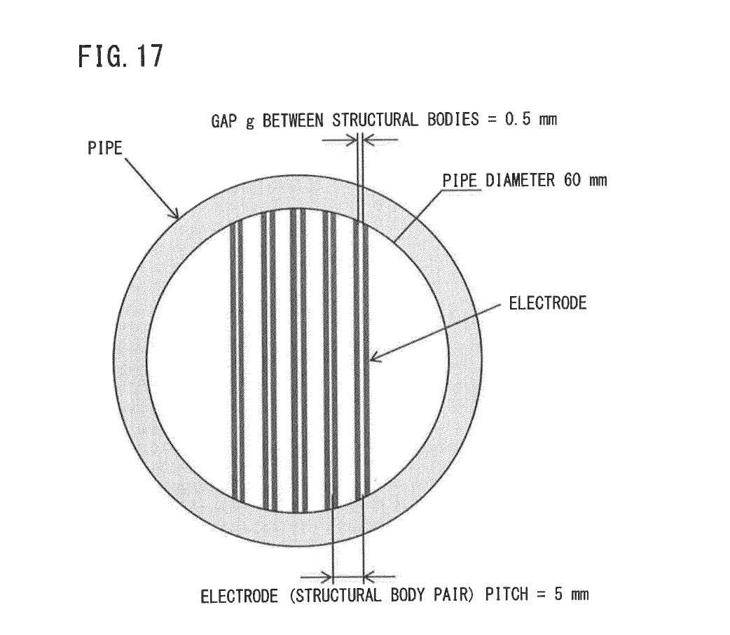

The pressure losses were checked in the following manner. Specifically, as shown in FIG. 17, five electrodes (structural body pairs) having the same structure were provided in a pipe having a circular shape in cross section (pipe diameter=60 mm, pipe length=500 mm). The pipe length is a length of the pipe for measuring the pressure loss, and this is a distance for measuring the pressure difference. Further, for development of the flow in the pipe (i.e., for formation of the flow having parabolic velocity distribution in the pipe), segments each having the length of 200 mm were provided on upstream and downstream sides of the pipe. Therefore, the total length including the pipe and the segments on the upstream and downstream sides was 900 mm. Further, the air at room temperature was supplied into the pipe at the flow rate of 250 liter/min. The pressure difference between the inlet and the outlet of the pipe was measured as the pressure loss.

The five electrodes (structural body pairs) in the pipe were positioned at the center in the pipe, i.e., at the point remote from the pressure measurement points by 250 mm. The electrodes were arranged at the pitch of 5 mm, and the gap g between the structural bodies of each electrode was 0.5 mm.

The details of the structural bodies according to the embodiments 1 to 6 and the comparative example 1 are as follows:

### Comparative Example 1

The structural body according to the comparative example 1 was based on the first structural body 10A shown in FIG. 1A, and had the relationship: Dix/Diy=1.0 where Dix was the length of the insulating body 16 in the typical flow direction x and Diy was the maximum value of the length of the insulating body 16 in the direction y perpendicular to the typical flow direction x.

### Embodiment 1

The structural body according to the embodiment 1 was based on the first structural body 10A shown in FIG. 1A, and had the relationship: Dix/Diy=1.5 where Dix was the length of the insulating body 16 in the typical flow direction x and Diy was the maximum value of the length of the insulating body 16 in the direction y perpendicular to the typical flow direction x.

### Embodiments 2 to 6

The structural bodies according to the embodiments 2 to 6 had substantially the same structure as the structural body according to the embodiment 1. However, the structural bodies according to the embodiments 2 to 6 were different from the structural body according to the embodiment 1 in that the embodiments 2 to 6 were based on the first structural body 10A shown in FIG. 1A, and had values of 2.0, 10.0, 3.3, 3.0, and 5.5, respectively, for the relationship between the length Dix and the maximum value Diy (Dix/Diy).

### (Evaluation)

The pressure losses in the comparative example 1 and the embodiments 1 to 6 were checked. In all of the embodiments 1 to 6, the pressure losses were not more than 200 kPa, and the results were evaluated as suitable. In contrast, in the comparative example 1, the pressure loss exceeded 200 kPa.

### Second Embodiment

In the same manner as in the case of the first embodiment, as shown in FIG. 17, five electrodes (structural body pairs) having the same structure were provided in a pipe having a circular shape in cross section (pipe diameter=60 mm, pipe length=500 mm).

In each of electrode structures according to embodiments 11 to 22 and a comparative example 2, the ozone generation efficiency was checked. The ozone generation efficiency was measured based on ozone concentration in an exhaust gas at a certain level of power supply and at a certain gas flow rate.

### (Method of Checking Ozone Generation Efficiency)

Firstly, in order to check the ozone generation efficiency, the air was used as a raw fuel gas. The gas flow rate was 2.5 NL/min, and the gas pressure was 0.25 MPa.

As the power source for discharging electricity, an alternating current power source capable of outputting electricity at the voltage (amplitude) of ±4 kV, and at the frequency of 20 kHz was used.

Under the above conditions, the ozone concentration in the exhaust gas was measured using an ozone concentration monitor (EG-3000D (manufactured by Ebara Jitsugyo Co., Ltd.)).

The details of the electrode structures according to the embodiments 11 to 22 and the comparative example 2 are as follows:

### Embodiment 11

As shown in FIG. 1B, in the electrode structure according to the embodiment 11, the two first electrode structural bodies 10A were provided to face each other, and alternating current voltage was applied between the conducting body 18 of one of the first structural bodies 10A and the conducting body 18 of the other of the first structural bodies 10A. A gap g formed between the first structural bodies 10A was 0.5 mm. The number of conducting bodies 18 (conducting body number) in each of the first structural bodies 10A was 1, and the relationship between the maximum value Dcx of the length of the conducting body 18 in the typical flow direction x and the maximum value Dcy of the length of the conducting body 18 in the direction y perpendicular to the typical flow direction x (Dcx/Dcy) had a value of 1.2. The shape of the insulating body 16 was the same as that of the above described embodiment 1.

### Embodiments 12 to 16

Electrode structures according to the embodiments 12 to 16 had the same structure as the electrode structure according to the embodiment 11. However, the electrode structures according to the embodiments 12 to 16 were different from the electrode structure according to the embodiment 11 in that the electrode structures according to the embodiments 12 to 16 had values of 3.0, 12.0, 8.0, 4.0, and 7.0, respectively, for the relationship between the maximum value Dcx and the maximum value Dcy of the length (Dcx/Dcy). Further, the shapes of the insulating bodies 16 of the embodiments 12 to 16 were the same as those of the above described embodiments 2 to 6, respectively.

### Embodiment 17

In the electrode structure according to the embodiment 17, as shown in FIG. 2B, the two second structural bodies 103 were provided to face each other, and alternating current voltage was applied between the conducting body 18 of one of the second structural bodies 10B and the conducting body 18 of the other of the second structural bodies 10B. The gap g between the second structural bodies 10B was 0.5 mm. The number of the conducting bodies 18 (conducting body number) was 2, and the relationship between the maximum value Dcx and the maximum value Dcy of the length (Dcx/Dcy) had a value of 2.0. Regarding the shape of the insulating body 16, the relationship between the length Dix and the maximum value Diy (Dix/Diy) had a value of 1.5.

### Embodiments 18 to 22

Electrode structures according to the embodiments 18 to 22 had the same structure as the electrode structure according to the embodiment 17. However, the electrode structures according to the embodiments 18 to 22 were different from the electrode structure according to the embodiment 17 in that the numbers of the conducting bodies 18 in the embodiments 18 to 22 were 6, 12, 6, 3, 7, respectively, and the embodiments 18 to 22 had values of 6.0, 12.0, 6.0, 3.0, and 7.0, respectively, for the relationship between the sum Dcx of the maximum values and the maximum value Dcy (Dcx/Dcy). Further, regarding the shapes of the insulating bodies 16 of the embodiments 18 to 22, the relationship between the length Dix and the maximum value Diy (Dix/Diy) had values of 5.5, 15.0, 3.3, 3.0, and 5.5, respectively.

### Comparative Example 2

The electrode structure according to the comparative example 2 was substantially the same as the electrode structure according to the embodiment 11. However, the electrode structure according to the comparative example 2 was different from the electrode structure according to the embodiment 11 in that the relationship between the sum Dcx of the maximum values and the maximum value Dcy (Dcx/Dcy) had a value of 1.0. Further, regarding the shape of the insulating body 16, the relationship (Dix/Diy) between the length Dix and the maximum value Diy had a value of 1.0.

### (Evaluation)

As for the ozone generation efficiency, the difference in the ozone generation efficiency in the comparative example 2 and the embodiments 11 to 22 were evaluated relatively, assuming that the ozone generation efficiency in the comparative example 2 was 1.0. The details of the comparative example 2 and the embodiments 11 to 22 and their evaluation results are shown in the following table 1.

TABLE 1

| | Shape of | | | | Shape of | | | |
|---|---|---|---|---|---|---|---|---|
| | Conducting Body | | | | Insulating Body | | | |
| | | Dcx | Dcy | Dcx/ | Dix | Diy | Dix/ | |
| | *1 | (mm) | (mm) | Dcy | (mm) | (mm) | Diy | *2 |
| Comparative | 1 | 0.5 | 0.5 | 1.0 | 1.0 | 1.0 | 1.0 | 1.0 |
| Example 2 | | | | | | | | |
| Embodiment 11 | 1 | 0.6 | 0.5 | 1.2 | 1.5 | 1.0 | 1.5 | 1.2 |
| Embodiment 12 | 1 | 1.5 | 0.5 | 3.0 | 2.0 | 1.0 | 2.0 | 2.9 |
| Embodiment 13 | 1 | 6.0 | 0.5 | 12.0 | 10.0 | 1.0 | 10.0 | 10.0 |
| Embodiment 14 | 1 | 1.6 | 0.2 | 8.0 | 2.3 | 0.7 | 3.3 | 3.0 |
| Embodiment 15 | 1 | 4.0 | 1.0 | 4.0 | 6.0 | 2.0 | 3.0 | 7.3 |
| Embodiment 16 | 1 | 7.0 | 1.0 | 7.0 | 11.0 | 2.0 | 5.5 | 11.2 |
| Embodiment 17 | 2 | 1.0 | 0.5 | 2.0 | 1.5 | 1.0 | 1.5 | 1.8 |
| Embodiment 18 | 6 | 3.0 | 0.5 | 6.0 | 5.5 | 1.0 | 5.5 | 5.5 |
| Embodiment 19 | 12 | 7.2 | 0.6 | 12.0 | 15.0 | 1.0 | 15.0 | 11.5 |
| Embodiment 20 | 6 | 1.2 | 0.2 | 6.0 | 2.3 | 0.7 | 3.3 | 2.0 |
| Embodiment 21 | 3 | 3.0 | 1.0 | 3.0 | 6.0 | 2.0 | 3.0 | 5.7 |
| Embodiment 22 | 7 | 7.0 | 1.0 | 7.0 | 11.0 | 2.0 | 5.5 | 11.0 |

*1 Conducting Body Number
*2 Ozone Generation Efficiency

As can be seen from the table 1, all of the ozone generation efficiencies in the embodiments 11 to 22 are better than the ozone generation efficiency in the comparative example 2. In particular, as can be seen from the embodiments 13, 16, 19, and 22, the larger the ratio Dcx/Dcy becomes, the higher the efficiency becomes. It is considered that the electric field is generated in a planar wider area, and for this reason, improvement in the ozone generation efficiency is achieved. However, same as the embodiments 14 and 20, even if the ratio Dcx/Dcy is large, in the case where Dix in the shape of the insulating body (maximum value of the length of the insulating body 16 in the typical flow length direction x) is less than 2.5 mm, improvement in the ozone generation efficiency is limited.

### Third Embodiment

The ozone generation efficiencies in the electrode structures according to embodiments 31 to 36 and a reference example 1 were checked. As with the case of the second embodiment, the ozone generation efficiencies were measured based on the ozone concentration in an exhaust gas at a certain level of power supply and at a certain gas flow rate. The method of checking the ozone generation efficiencies is the same as in the case of the second embodiment, and description thereof is omitted.

The details of the electrode structures according to the embodiments 31 to 36 and the reference example 1 are as follows:

### Embodiment 31

In the electrode structure according to the embodiment 31, as shown in FIG. 15A, the two structural bodies 10Ba of the first modified example of the second structural body 10B were provided to face each other, and alternating current voltage was applied between the conducting body 18 of one of the structural bodies 10Ba of the first modified example and the conducting body 18 of the other of the structural bodies 10Ba of the first modified example. The gap g between the structural bodies 10Ba of the first modified example was 0.5 mm. The relationship between the sum Dmn of the typical dimensions of the adjacent conducting bodies 18 in the structural bodies 10Ba of the first modified example and the distance Lmn between the centers of the conducting bodies 18 (Lmn/(Dmn/2)) had a value of 1.1. Further, regarding the shape of the insulating body 16, the relationship between the length Dix and the maximum value Diy (Dix/Diy) had a value of 4.5.

### Embodiments 32 to 36

Electrode structures according to the embodiments 32 to 36 had the same structure as the electrode structure according to the embodiment 31. However, the electrode structures according to the embodiments 32 to 36 were different from the electrode structure according to the embodiment 31 in that the electrode structures according to the embodiments 32 to 36 had values of 1.5, 2.0, 1.5, 1.1, and 2.0, respectively, for the relationship between the sum Dmn and the distance Lmn between the centers of the conducting bodies 18 (Lmn/(Dmn/2)). Further, regarding the shapes of the insulating bodies 16 of the embodiments 32 to 36, the relationship between the length Dix and the maximum value Diy (Dix/Diy) had values of 4.5, 4.5, 3.3, 3.0, and 3.0, respectively.

### Reference Example 1

Electrode structure according to the reference example 1 had substantially the same structure as the electrode structure according to the embodiment 31. However, the electrode structure according to the reference example 1 was different from the electrode structure according to the embodiment 31 in that the electrode structure according to the embodiment 31 had a value of 3.0 for the relationship between the sum Dmn and the distance Lmn between the centers of the conducting bodies 18 (Lmn/(Dmn/2)). Further, regarding the shape of the insulating body 16, the relationship between the length Dix and the maximum value Diy (Dix/Diy) had a value of 4.5.

### (Evaluation)

With regard to the ozone generation efficiency, in the same manner as in the case of the second embodiment described above, the differences in the ozone generation efficiencies among the embodiments 31 to 36 and the reference example 1 were evaluated relatively, assuming that the ozone generation efficiency of the embodiment 34 was 1.0. The details of the comparative example 1 and the embodiments 31 to 36 are shown in the following table 2.

TABLE 2

| | Distance Between | | | Shape of | | | |
|---|---|---|---|---|---|---|---|
| | Conducting Bodies | | | Insulating Body | | | |
| | Lmn | Dmn/2 | Lmn/ | Dix | Diy | Dix/ | |
| | (mm) | (mm) | (Dmn/2) | (mm) | (mm) | Diy | *1 |
| Reference | 1.5 | 0.5 | 3.0 | 4.5 | 1.0 | 4.5 | 2.0 |
| Example 1 | | | | | | | |
| Embodiment 31 | 0.55 | 0.5 | 1.1 | 4.5 | 1.0 | 4.5 | 2.8 |
| Embodiment 32 | 0.75 | 0.5 | 1.5 | 4.5 | 1.0 | 4.5 | 2.7 |
| Embodiment 33 | 1.0 | 0.5 | 2.0 | 4.5 | 1.0 | 4.5 | 2.5 |
| Embodiment 34 | 0.3 | 0.2 | 1.5 | 2.3 | 0.7 | 3.3 | 1.0 |
| Embodiment 35 | 1.1 | 1.0 | 1.1 | 6.0 | 2.0 | 3.0 | 5.8 |
| Embodiment 36 | 2.0 | 1.0 | 2.0 | 6.0 | 2.0 | 3.0 | 5.2 |

*1 Ozone Generation Efficiency

As can be seen from the table 2, the ozone generation efficiencies in the embodiments 31 to 33, 35, 36 are better than the ozone generation efficiency in the reference example 1. In particular, as can be seen from the results of the reference example 1 and the embodiments 31 to 33, the smaller the distance Lmn between the centers of the conducting bodies 18 becomes, the higher the efficiency becomes. This analysis is applicable to the embodiments 35 and 36 as well. It is considered that the electric field is generated in a planar wider area, and for this reason, improvement in the ozone generation efficiency is achieved. However, as shown in the embodiment 34, it has been found that, even if the ratio Dix/Diy is large, in the case where Dix in the shape of the insulating body (maximum value of the length of the insulating body 16 in the typical flow length direction x) is less than 2.5 mm, improvement in the ozone generation efficiency is limited. It should be noted that if the distance Lmn between the centers is too small, the insulating body 16 between the conducting bodies 18 becomes thin. Therefore, the insulating body 16 is vulnerable to impacts, and the mechanical strength of the insulating body 16 may not be sufficient undesirably.

It should be understood that the structural body and the electrode structure according to the present invention are not limited to those of the embodiments described above, and it is a matter of course that various structures can be adopted without deviating the gist of the present invention.

What is claimed is:

1. A structural body provided in fluid, perpendicular to a typical flow direction of the fluid, the structural body comprising:
a cylindrical insulating body having at least one hollow portion; and
at least one conducting body positioned in the hollow portion of the insulating body,
wherein in a cross section of the insulating body having a normal line in an axial direction of the insulating body, a following relationship is satisfied:
1.5×Diy≦Dix≦15×Diy
where Dix is a length of the insulating body in the typical flow direction and Diy is a maximum value of a length of the insulating body in a direction perpendicular to the typical flow direction.

2. The structural body according to claim 1, wherein in the cross section, a following relationship is satisfied:
1.2×Dcy≦Dcx≦12×Dcy
where Dcx is a length of the conducting body in the typical flow direction and Dcy is a maximum value of a length of the conducting body in the direction perpendicular to the typical flow direction.

3. The structural body according to claim 2, wherein the insulating body has a plurality of the hollow portions containing a plurality of the conducting bodies, respectively; and
same potential is applied to each of the conducting bodies.

4. The structural body according to claim 3, wherein a plurality of the conducting bodies are arranged in the typical flow direction, and the Dcx represents a sum of lengths of the conducting bodies arranged in the typical flow direction.

5. The structural body according to claim 3, wherein a plurality of the conducting bodies are arranged in the direction perpendicular to the typical flow direction, and the Dcy represents a maximum value of lengths of the conducting bodies arranged in the direction perpendicular to the typical flow direction.

6. The structural body according to claim 3, wherein a following relationship is satisfied:
1.1×Dmn/2≦Lmn≦2.0×Dmn/2
where Dmn is a sum of typical dimensions of at least a pair of adjacent conducting bodies among the plurality of the conducting bodies and Lmn is a distance between centers of the conducting bodies.

7. The structural body according to claim 1, wherein in the cross section, at least one of an upstream end and a downstream end of the insulating body with respect to flow of the fluid has a shape where a length perpendicular to the typical flow direction is decreased gradually toward a front end of the insulating body.

8. The structural body according to claim 7, wherein the at least one of the upstream end and the downstream end includes at least one tapered portion.

9. The structural body according to claim 7, wherein the front end has a curved shape configured to satisfy the following relationship:
0.05×Diy≦2×Rt≦0.7×Diy
where Rt is a radius of curvature of the curved shape.

10. The structural body according to claim 1, wherein the insulating body has an upstream end and a downstream end with respect to flow of the fluid, and at least the upstream end has a shape where a length in a direction perpendicular to the typical flow direction and perpendicular to a longitudinal direction of the insulating body is decreased gradually toward a front end of the insulating body.

11. The structural body according to claim 10, wherein the insulating body includes a front surface and a back surface extending in parallel to flow of the fluid, and the front surface includes a tapered surface at the upstream end of the insulating body and the back surface includes a flat surface at the upstream end of the insulating body.

12. The structural body according to claim 10, wherein the insulating body includes a front surface and a back surface extending in parallel to flow of the fluid, and the front surface includes a flat surface at the upstream end of the insulating body and the back surface includes a tapered surface at the upstream end of the insulating body.

13. The structural body according to claim 10, wherein the insulating body includes a front surface and a back surface extending in parallel to flow of the fluid, and the front surface includes a tapered surface at the upstream end of the insulating body and the back surface includes a tapered surface at the upstream end of the insulating body.

14. The structural body according to claim 1, wherein the insulating body has an upstream end and a downstream end with respect to flow of the fluid, at least the downstream end has a shape where a length in a direction perpendicular to the typical flow direction and perpendicular to a longitudinal direction of the insulating body is decreased gradually toward a front end of the insulating body.

15. The structural body according to claim 14, wherein the insulating body includes a front surface and a back surface extending in parallel to flow of the fluid, and the front surface includes a tapered surface at the downstream end of the insulating body and the back surface includes a flat surface at the downstream end of the insulating body.

16. The structural body according to claim 14, wherein the insulating body includes a front surface and a back surface extending in parallel to flow of the fluid, and the front surface includes a flat surface at the downstream end of the insulating body and the back surface includes a tapered surface at the downstream end of the insulating body.

17. The structural body according to claim 14, wherein the insulating body includes a front surface and a back surface extending in parallel to flow of the fluid, and the front surface includes a tapered surface at the downstream end of the insulating body and the back surface includes a tapered surface at the downstream end of the insulating body.

18. The structural body according to claim 1, wherein the insulating body and the conducting body are directly joined together integrally by firing.

19. A structural body comprising
a cylindrical insulating body having at least one hollow portion; and
at least one conducting body positioned in the hollow portion of the insulating body,
wherein in a cross section of the insulating body having a normal line in an axial direction of the insulating body, a following relationship is satisfied:
1.5×Diy≦Dix≦15×Diy
where Dix is a length of the insulating body in a first direction, and Diy is a maximum value of a length of the insulating body in a second direction perpendicular to the first direction;
in the cross section, a following relationship is satisfied:
1.2×Dcy≦Dcx≦12×Dcy
where Dcx is a length of the conducting body in the first direction and Dcy is a maximum value of a length of the conducting body in the second direction.

20. An electrode structure having at least two structural bodies according to claim 1, wherein alternating current voltage is applied between the conducting body of one of the structural bodies and the conducting body of another of the structural bodies; and
the one of the structural bodies and the other of the structural bodies are arranged such that an axial direction of the insulating body is oriented in perpendicular to the typical flow direction.
